(19) United States
(12) Patent Application Publication
(10) Pub. No.: US 2012/0310555 A1
(43) Pub. Date: Dec. 6, 2012

(54) Method and Apparatus for Monitoring Power Transmission in an Electric Power Transmission Network

(76) Inventor: Pål Even Gaarder, Oslo (NO)

(21) Appl. No.: 13/118,696

(22) Filed: May 31, 2011

(51) Int. Cl. G06F 19/00; G01R 33/02

(52) U.S. Cl. 702/57; 324/244

(57) ABSTRACT

An apparatus and method for measurement of power in an electric power transmission line and disturbances in a power grid is disclosed. The apparatus comprises a magnetic field sensor with at least two sensing coils for measuring the magnetic field at the electric power transmission line and transmitting magnetic field data to a processor. The magnetic field sensor is arranged proximate to but at a distance from the electric power transmission line.

### CROSS-REFERENCE TO RELATED APPLICATIONS

This application is related to U.S. patent application Ser. No. 12/678,272 filed on 10 Sep. 2010 entitled “Method and Apparatus for Monitoring Power Transmission”. The application is being concurrently filed in the United States and the United Kingdom.

### BACKGROUND OF THE INVENTION

1. Field of the Invention

The field of the present invention relates to an apparatus and method for measurement of power in an electric power transmission line.

2. Background of the Invention

The traditional monopolies of electrical utility companies have been relaxed in the past few years in the European Union, in the United States and in other countries. There has developed as a result a growing wholesale market for electrical power. Utility companies, independent power producers, and power marketers as well as brokers are some of the participants in the volatile electricity supply market. It is known, for example, that variables such as the time of day and date, weather, temperature and oil prices play a role in the pricing of electricity in a given region. Furthermore, the pricing of the electricity is dependent on the operational status of electric generation and use facilities in that region as well as the transmission capacity of an electric power transmission network (also called a power grid). The participants in the electric power markets require access to real-time information as well as historical data on the operational status of the electric generation and use facilities as well as the electric power transmission lines in the region. This information allows the development of trading strategies in electric power and responses to power system events (such as disruptions in the power grid due to failures of transformers).

The relaxation of the monopoly status of traditional electric utilities has resulted in increased competition for customers among suppliers of electric power. Information relating to the use of electric power by the potential customers would be useful to those involved in the bidding for electrical supply contracts. It would also be further advantageous to determine information on the supply and the demand of the electric power over time without having to directly connect to the electrical power transmission lines.

Methods and systems for the measurement for the electric power transmission are known from several prior art documents. For example, U.S. Pat. No. 6,714,000 (Staats, assigned to Genscape, Inc.) teaches a method for the remote monitoring of the magnitude and the direction of net electrical power and current flow to or from a facility over a prolonged period of time. The method described in the Staats '000 patent application includes the detection and the measurement of the magnetic field emanating from the monitored electrical power transmission lines and detecting a signal that is synchronized to the power system frequency emanating from the power lines. The method further includes evaluation, storing and transmission of the data on the electromagnetic field that emanates from the electrical power transmission line.

A further International Patent Application No. WO2006/112839 (Genscape Intangible Holding, Inc.) also teaches a method and a system for the substantially real-time monitoring of the operational dynamics of power plants and other components in an AC (alternating current) power grid. The substantially real-time monitoring of the WO '398 application is done by using information collected from a network of power grid frequency detection and reporting devices. The teachings of the disclosure allow the real-time detection and reporting of certain power grid events, such as a power plant trips or failures.

International Patent Application No. WO2007/030121 (Genscape Intangible Holding, Inc.) teaches a system for monitoring the power flow along an electric power transmission line, which includes a plurality of magnetic field monitors placed at selected positions. The magnetic field monitors have two magnetometers with their sensitive axis placed either in the horizontal or vertical direction. A detailed description of such magnetic field monitors is found in U.S. Pat. No. 6,771,058 (Lapinski). The system further includes a central processing facility for the communication of the power flow to an end user.

European Patent No. EP1 297 347 (Genscape Intangible Holding, Inc.) discloses an apparatus for remotely measuring and monitoring an electric power transmission line. The apparatus comprises a first sensor which is responsive to a first component of a magnetic flux density associated with the electric power transmission lines and which outputs a volt proportional to the magnetic flux density generated by current flowing through that electrical power transmission line. The apparatus further includes a second sensor that outputs a voltage proportional to a net electrical potential associated with the electrical power transmission line. The values for the voltage and the current flowing through the electrical power transmission line are passed to a central processing facility which combines the phase of the measured electrical potential with the phase of the measured magnetic flux density in order to determine the phase of the electrical potential relative to the magnetic flux density and that by determining from the face of the electrical potential relative to the magnetic flux density. The phase angle of the current flowing through the electrical power transmission line with respect to the voltage of the transmission line is also determined. A power factor on the electric power transmission line and the magnitude and the direction of the power flowing through the electrical power transmission line is thereby calculated. It should be noted that the voltage sensor and the magnetic flux sensor are substantially co-located, as can be seen from FIG. 1 of the patent.

Other companies also measure power flowing along electric power transmission lines. For example, the Norwegian company powermonitor.org supplies information about the German power plants. Their product is described in the article “Slik drives strom-spionasje”, Økonomisk Rapport 04/2006, 40-41. Another Norwegian company, Energieinfo A S, Stavern, has filed a Norwegian patent application entitled “Fremgangsmåte og apparat for overvakning av produksjon og overforing av elektrisk kraft” (Application No. NO 2007 2653).

Two sensing coils for measuring the current passing through a power line are known from U.S. Pat. No. 5,793,587 (Boteler, assigned to Hubbell Inc.). All of the power line conductors pass through the primary winding of both of the sensing coils A grounding conductor line passes through the primary winding of only one of the sensing coils. The two sensing coils of the Boteler '587 disclosure are used to detect ground leakage current.

### SUMMARY OF THE INVENTION

The disclosure teaches an apparatus for measuring a magnetic field about an electric power transmission line. The apparatus comprises at least two first sensing coils, which are disposed about a first axis and spaced at first distance from each other. The electric power transmission line follows substantially a second axis which is spaced apart from and at a second distance from the first axis. In other words the electric power transmission line does not pass through the centre of the at least two first sensing coils. The use of several sensing coils at same axis provides further data that allow a better and more precise determination of the magnetic field about multiple electric power transmission lines. The apparatus may further comprise a processor which is selectably connectable to one or more of the at least two first sensing coils. The processor is able to calculate a signal that is representative of strength of the magnetic field about the electric power transmission line and which is representative of the current flowing through the electric power transmission line.

The calculation of the signal representative of the strength of the magnetic field enables the power and the direction of transmission of the electric power in the electric power transmission line to be measured in substantially real time. The term “real time” in the context of this disclosure means that the calculation of the electric power is carried out within a time frame of less than typically milliseconds.

The apparatus may also comprise one or more second sensing coils which are arranged at an angle to the at least two first sensing coils and are also connected to the processor. The processor is able to use the additional information obtained from the second sensing coils in order to calculate better the direction of flows and the value of the electric power flowing in the electric power transmission line. In particular the use of the second sensing coils provides further data that allows a better calculation of the magnetic field about multiple electric power transmission lines. Typically the second sensing coils are arranged substantially orthogonal to the first sensing coils

The apparatus further comprises a position measuring unit, using for example GPS measurement, and a time measuring unit. The time measuring unit can also use the GPS signals supplied by geostationary satellites. It will, of course, be appreciated that both the position and the time may be measured using other devices.

The apparatus of this disclosure typically further comprises a data transmission module that is able to transmit data relating to the signal representative of the strength of the magnetic field about the electric power transmission line to a central processing system. The data transmission module is typically connected to a wireless network, but could also be connected through fixed line.

In order to supply power to the apparatus of this disclosure, the apparatus may be further equipped with a solar power unit to make it substantially independent of mains supply.

The disclosure also teaches a method for the measurement of the magnetic field about the electric power transmission line which comprises measuring a current induced in a first sensing coil, measuring a current induced in a second sensing coil and measuring currents induced in both of the first sensing coils and the second sensing coil to enable the calculation of a value representative of the strength of the magnetic field. It will be appreciated that the calculation of the values is carried out at periodic intervals in order to determine whether the electric power transmitted on the electric power transmission line has changed.

The apparatus may further comprise one or more time tag reference stations. The time tag reference stations may be connected to the lower voltage part of the power grid.

The apparatus and method of the current invention allow the measurement of the power factor—including both active and reactive power and also enable the measurement of the deviation of the power factor from the expected power factor.

### DESCRIPTION OF THE FIGURES

FIG. 1 shows an overview of the system in accordance with a preferred embodiment of the present invention.

FIG. 2 shows a magnetic field sensor in accordance with a preferred embodiment of the present invention.

FIGS. 3A and 3B show an example of the magnetic field sensor in accordance with a preferred embodiment of the present invention.

### DETAILED DESCRIPTION OF THE INVENTION

For a complete understanding of the present invention and the advantages thereof, reference is now made to the following detailed description taken in conjunction with the Figures.

It should be appreciated that the various aspects of the invention discussed herein are merely illustrative of the specific ways to make and use the invention and do not therefore limit the scope of invention when taken into consideration with the claims and the following detailed description. It will be further appreciated that features from one embodiment of the invention may be combined with features from other embodiments of the invention.

The teachings of the cited documents should be incorporated by reference into the description.

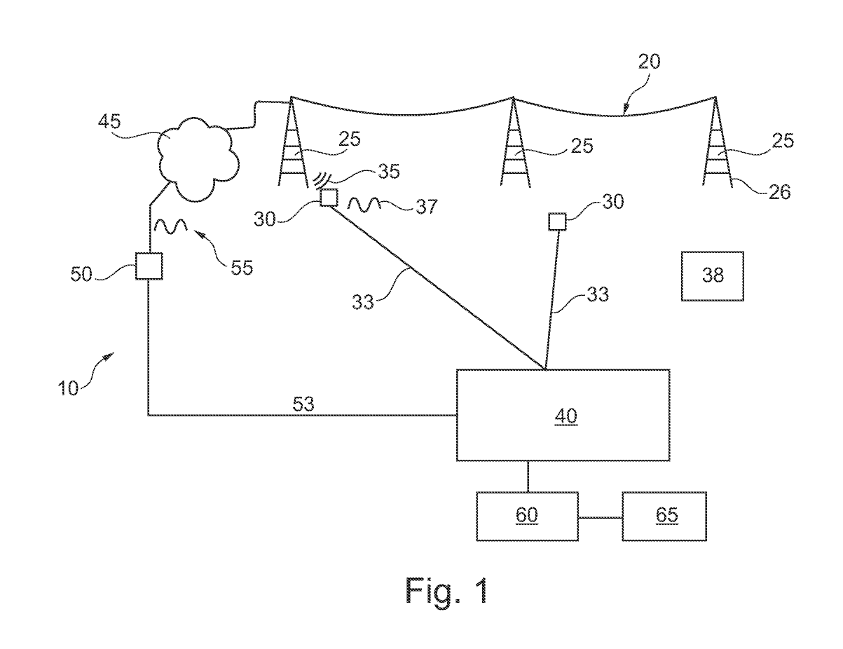

FIG. 1 shows an example of an apparatus according to this disclosure. FIG. 1 shows the system 10 for the measurement of power in an electric power transmission line 20. The system 10 is part of a high voltage electrical power transmission network (also termed “high voltage power grid”) carrying alternating current (AC), as will be explained later. The high voltage power grid is part of a power network, which also includes low voltage parts. The electric power transmission line 20 is shown in FIG. 1 as a single line strung between pylons 25. It will be appreciated that the electric power transmission line 20 will be generally made up of multiple lines strung between innumerable ones of the pylons 25. The line between the tip of each of the pylons 25 forms a transmission line axis and the electric power transmission line 20 will follow the direction of this transmission. Each of the multiple lines will carry a separate current and have a magnetic field 35 about the multiple lines. It will also be appreciated that the electric power transmission lines 20 may be laid on a surface or buried underground.

One or more magnetic field sensors 30 are mounted at a distance from the electric power transmission line 20. The magnetic field sensors 30 measure the magnetic field 35 generated by the electric power transmission line 20. The magnetic field 35 can be measured in an X-direction and a Y-direction that are generally orthogonal to each other. Advantageously the one or more magnetic field sensors 30 are arranged close to a base 26 of the pylons 25. This is because the electric power transmission line 20 sags between any two of the pylons 35. The sag of the electric power transmission line 20 will increase in hot weather and also the electric power transmission line 20 may move during storms due to wind. The movement and/or sag of the electric power transmission line 30 will affect the magnetic field 35. If, however, the magnetic field sensors 30 are arranged close to the base 26 of the pylons 25—at which point the electric power transmission line 20 is fixed—then the sag and/or movement of the electric power transmission line 20 will be substantially eliminated.

Typically the magnetic field sensors 30 are placed between 25 and 400 m from the electric power transmission lines. The exact coordinates of the magnetic field sensors 30 are measured, for example, using the Global Positioning System (GPS), as the information about the exact coordinates is needed to identify the electric power transmission line 20 being measured but also to calculate the power being transmitted over the electric power transmission line 20 and to record disturbances in the power grid as will be explained later. It will however, be appreciated that other means may be used to determine the exact coordinates of the magnetic field sensors 30, such as the European Galileo system, or trigonometric measurements using fixed points. The signals supplied by the GPS system may also be used to obtain highly accurate time signals, as will be explained later.

It will be further noted that FIG. 1 shows only two of the magnetic field sensors 30 arranged at the base 26 of two of the pylons 25 of the electric power transmission line 20. It will be noted that it is not necessary to have multiple magnetic field sensors 30 per pylon 25 or per electric power transmission line 20. Generally, there will be one magnetic field sensor 30 for one single electric power transmission line 20, and n or less magnetic field sensors 30, if n electric power transmission lines 25 are close to each other. The term “close” in the context of this disclosure means typically less than 1 km and usually only a few tens of meters. For example if there are two electric power transmission lines 20 at 30m distance (or two electric power transmission lines 20 at the same pylon 25) it is possible to use a single magnetic field sensor 30 (which measures both the magnetic fields in the X-direction and in the Y-direction and the phase/time). The reason for this is that both the time is measured very accurately (using the GPS system) and the peak of the magnetic field signal is accurately known. By inspecting the phase difference between the measurements in the X-direction and the Y-direction made by the magnetic field sensors 30 (inside the same measurement unit) is possible to solve the equation for the direction and magnitude of a current flowing in two electric power transmission lines 20 if, at the same time, the geometry of the electric power transmission lines 20 and the placement of the measurement unit with the magnetic field sensors 30 is known. The measurement is either done in real time (inside the measurement unit) or one needs to time tag the magnetic field measurements of both the X-direction and the Y-direction very accurately and do the computation afterwards. For calibration of the system 10 it is possible to use several measurement units with a plurality of the magnetic field sensors 30 at the same electric power transmission line 20 for a period of time.

FIG. 1 also shows a processor 40 connected to the plurality of magnetic field sensors 30 by first data lines 33. The first data lines 33 transfer in substantially real time magnetic field data 37 representing values of the magnetic field 35 measured by the magnetic sensor 30. A voltage sensor 50 is also connected to the processor 40 by second data lines 53. The second data lines 53 transfer in substantially real time voltage phase data 55 to the processor 40. The voltage sensor 50 is placed in the low voltage part of the electric power transmission network in this aspect of the disclosure. The low voltage part of the electric power transmission network is connected through transformers and other lines (represented by reference numeral 45) to the high voltage power grid.

It will be noted that the processor 40 does not need to be situated close to the plurality of magnetic field sensors 30. Similarly the processor 40 does not need to be situated close to the voltage sensor 50. The voltage sensor 50 needs to be connected to the same AC network as the electric power transmission line 20. In other words, there can be no DC connection between the voltage sensor 50 and the electric power transmission line 20. In Europe this requirement is met, for example, in the electric power grid of central Europe (i.e. Germany, Denmark, Netherlands, Belgium, France) and the electric power grid of Scandinavia (Sweden, Norway).

FIG. 1 also shows a clock 38. The clock 38 is highly accurate and is used to send time signals to local clocks at the magnetic field sensors 30 and the processor 40. The clock 38 could be part of the GPS system. It is known, for example, that the GPS satellites in orbit transmit accurate time signals. The clock 38 could also be an earth-based atomic clock or obtain time signals from a mobile communications network.

It should be further noted that the processor 40 does not need to be situated in any specific country and indeed could be part of a cloud computing network since the processor 40 can acquire the magnetic field data 37 and/or the voltage waveform data 55 remotely. It will be noted that it is possible for the processor 40, the magnetic field sensor 30 and the voltage sensor 50 to be in different countries.

A transform phase calculator 60 is connected to the processor 40. Typically the transform phase calculator 60 will be implemented as a software module running on the processor 40, but the transform phase calculator 60 could also be implemented in hardware (as an ASIC chip) or run on a second processor (not shown). In one aspect of the invention the transform phase calculator 60 and routines and algorithms used by the transform phase calculator 60 have access to a look-up table 65 implemented as a database.

The system 10 shown in FIG. 1 is able by use of the magnetic field data 37 to determine the direction of the current flowing in the electric power transmission line 20 as the U-1 phase angle (to be explained later) and other power grid parameters. The other power grid parameters include, but are not limited to the configuration of the power grid, capacitive load, and HVDC load.

The system 10 is able to monitor and evaluate frequencies in the electric power transmission line 20. The frequencies include not only the nominal frequency (50 Hz in Europe; 60 Hz in US) but also higher and lower frequencies as and when required.

It will be recognized that the first data line 33 and the second data line 53 do not have to be physical cables or other fixed lines. The first data line 33 and the second data line 53 could also be constructed from the General Packet Radio Service (GPRS) over the GSM mobile communications network. Alternatively the first data line 33 and the second data line 53 could be implemented over the mobile communications network (e.g. the UMTS/3G mobile communications network or the LTE mobile communications network) as well as by radio or satellite etc.

The use of the mobile communications network requires significant amount of power for the establishment of upstream data channels and/or downstream data channels as short intervals of data relating to the magnetic field data 37 and the voltage waveform data 55 will need to be established and transferred across the mobile communications network. In one aspect of the invention the magnetic field data 37 and/or the voltage waveform data 55 is not sent in real-time to the processor 40. Instead the magnetic field data 37 and/or the voltage waveform data 55 is temporarily stored and transmitted in bursts of data packets across the mobile communications network. This procedure is to increase the time between each data transfer and thus reduce the rate of establishment of connections. The use of the fixed line communications network reduces power consumption.

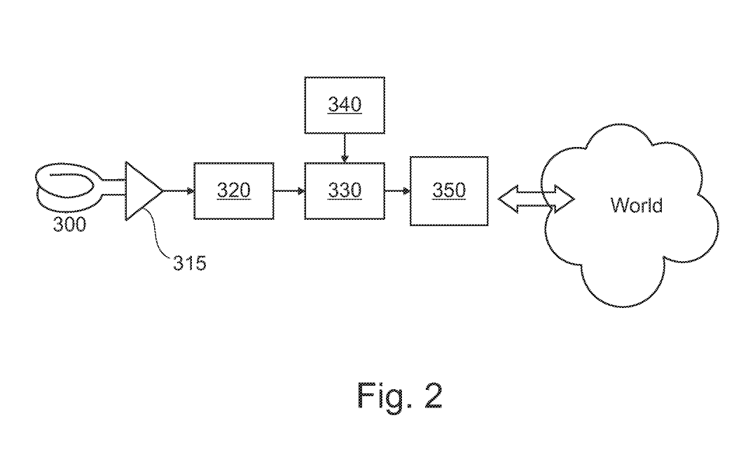

FIG. 2 shows an example of the magnetic field sensor 30 that comprises at least two sensing coils 300 connected to an amplifier 315 and then to an analog-digital converter 320. As discussed above, the magnetic field sensor 30 measures the magnetic flux in the magnetic field close to the electric power transmission lines 20 in real-time and is typically placed 25˜400 m away from the electric power transmission line 20. The magnetic field sensor 30 is typically configured to measure the magnetic field at suitable time intervals, but also if needed may be configured to measure the change of the flux of the magnetic field continuously. The measurements taken of the magnetic field may be the bottom-peak value, the integral, the shape, the frequency etc.

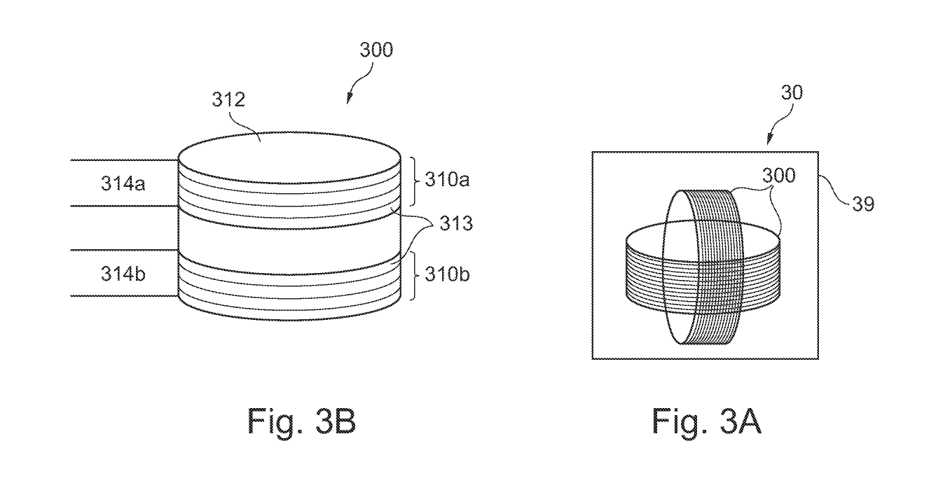

FIGS. 3A and 3B shows an example of a design of the magnetic field sensor 30 used in one aspect of the invention. The magnetic field sensor 30 comprises two sensing coils 300 that are placed substantially orthogonally to each other inside a watertight container 39, as shown in FIG. 3A. It will be appreciated that the two sensing coils 100 do not need to be exactly orthogonal to each other. It will suffice that different orthogonal components of the magnetic field 35 can be measured, i.e. the components in the X-direction and the Y-direction.

FIG. 3B shows an example of each one of the magnetic coils 300 inside the container 39. The sensing coil 300 has a first sensing coil 310a and a separately switchable second sensing coil 310b. Both the first sensing coil 310a and the second sensing coil 310b are wound around the same former 312 and are thus substantially coaxially located but spaced at a distance and have the same diameter, typically 20 cm, although this is not limiting of the invention. Each one of the first sensing coil 310a and the second sensing coil 310b has a plurality of windings which are typically made of copper wire. The magnetic field within the first sensing coil 310a can be measured at a first tap 314a and the magnetic field within the second sensing coil 310b can be measured at a second tap 314b. In addition, the first sensing coil 310a and the second sensing coil 310b can be switched together to form a larger sensing coil which magnetic field can be measured between the first tap 314a and the second tap 314b.

Using the magnetic coil 300 in this aspect enables three independent measurements at different points along same axis to be made of the magnetic field emanating from the electric power transmission line 20. The axis of the magnetic coil 300 is spaced apart from the transmission line axis (pylon-to-pylon axis) defined above. The first measurement can be made using the first sensing coil 310a, a second measurement can be made using the second sensing coil 310b and a third measurement can be made by using the combination of the first sensing coil 310a and the second sensing coil 310b switched together. This enables one sensing coil to have three different measurements of the same magnetic field 35. Each one of the three different measurements is made at slightly different points in the space and therefore each one of these measurements supply data for the calculation of the magnetic field 35. These measurements can be used to generate an overdetermined matrix which can be solved for several unknowns.

In one aspect of the invention the overdetermined matrix can be used to solve for additional several variables or unknowns. As an example, sag of the electric power transmission line 20 can be calculated, or non-uniform distribution of the current in each of the phases on the electric power transmission line 20 can be calculated. A more accurate position of the magnetic field sensor 30 relative to the electric power transmission line 20 can be calculated.

Each one of the first sensing coil 310a and the second sensing coil 310b outputs a voltage signal substantially proportional to the change per time in the magnetic flux through the internal diameter of the first sensing coil 310a and/or the second sensing coil 310b. It should be noted that other types of magnetic sensors could be used. An A/D converter 320 is connected to the first tap 314a and/or the second tape 314b. The A/D converter 320 converts the measured voltage values from the first sensing coil 310a and the second sensing coil 310b to digital values.

The magnetic field sensor 30 further includes a microprocessor 330 which processes the digital values from the A/D converter 320 and a global positioning and time unit 340 which measures the exact position of the magnetic field sensor 30, usually using the GPS system and also the time. The magnetic field sensor 30 includes a mobile data transmission module 350 for transmitting the data to the processor 40.

If needed dampening or amplification can be done between the coil and the A/D converter.

A MUX (multiplexer) or switch can be used in between the A/D converter and the different signal outputs from the coil. By this same electrical system and A/D converter can be used for several different coils. By this the calibration of the amplification and A/D converting will be the same for each coil.

The magnetic field sensor 30 has an exact known position in space as discussed above. The global positioning and time unit 340 with the microprocessor 330 is able to very accurately tag all of the measurements with the given time at the given place of the magnetic field sensor 30. In combination with the overall global position and timing system it is therefore possible for the processor 40 to treat all of the magnetic field sensors 30 in the system as a single composite unit which virtually operates in real-time.

Let us take an example. Consider a 50 ms long snapshot of the current signal over the whole power grid taken at the same time. The electric power transmission lines 20 surrounding the magnetic field sensors have an exact known position in space. This known position can be either be relative to the magnetic field sensors 30, it can be obtained from official information such as maps etc., or from measurements made using mobile GPS units, etc. Using this known position it is possible to make a mathematical model of the magnetic field at which the magnetic field sensor 30 is placed and to set up equations describing how the magnetic field is dependent on the current in the electrical power transmission lines 20. Basic linear algebra, for example, can be used to solve these equations.

The Global Grid Position and Timing system (GGPT) units 340 are placed in all of the measurement units such as the magnetic field sensors 30, the processor 40 and the voltage sensor 50 and provide accurate time data for all parts of the system. The GGPT units 340 are represented on FIG. 1 as the clock 38. The GGPT units 340 allow spatial data to be computed based on geometry and the variation of signal speed with time. The GGPT units 340 have an accuracy and resolution typically down to nano-seconds and less than one meter in time and space. The accuracy serves as the basis for evaluating the transfer of a given power signal on the power grid from one location to another location. In a further aspect of the invention the time is measured as the point at which the voltage signal crosses the average voltage value.

Since the magnetic field sensors 30 are normally solar/battery powered, it is desirable to use as little power as possible in the magnetic field sensor 30. Normally the measurements that are done in intervals will be sent in data packets from time to time. To reduce the size of the data packets, algorithms can be used to compress the data. In addition the data packets will be temporarily stored (or never sent) if the measured changes from measurement to measurement are within certain limits. In this way the size of the data packets can possible be increased, but there will be less data packets to send. The average power consumption over a time period (example 24 h) is normally much more closely related to the number of packets transmitted separately than the size of the data packets. In other words the power consumed is mainly related to the number of connections the transmitters establish with the receiver.

In addition to more standard methods to reduce the number of data size and data packets as mentioned above, the magnetic field sensor 30 can have a data prediction module as described earlier that reduces the number of upstream and downstream data packet transfers. This makes the data transport more efficient and reduces the power consumption significantly.

The invention has been described with respect to the measurement of the magnetic field at the electric power transmission line and the voltage waveform at a distance. It will be appreciated that it would be possible to measure the voltage at the electric power transmission line and the current at a distance or any combination of current and/or voltage data in order to obtain the transfer function. Furthermore, it is possible to measure the current and/or voltage at more than one point.

The foregoing description of the preferred embodiment of the invention has been presented for purposes of illustration and description. It is not intended to be exhaustive or to limit the invention to the precise form disclosed, and modifications and variations are possible in light of the above teachings or may be acquired from practice of the invention. The embodiment was chosen and described in order to explain the principles of the invention and its practical application to enable one skilled in the art to utilize the invention in various embodiments as are suited to the particular use contemplated. It is intended that the scope of the invention be defined by the claims appended hereto, and their equivalents. The entirety of each of the aforementioned documents is incorporated by reference herein.

| Reference Numerals | Names |
|---|---|
| 10 | Apparatus |
| 20 | Electric Power Transmission Line |
| 25 | Pylons |
| 26 | Base |
| 30 | Magnetic Field Sensor |
| 33 | First Datalines |
| 35 | Magnetic field |
| 37 | Magnetic Field Data |
| 38 | Clock |
| 39 | Container |
| 40 | Processor |
| 45 | Network |
| 50 | Voltage Sensor |
| 53 | Second data lines |
| 310 | Sensing coil |
| 310a | First sensing coil |
| 310b | Second sensing coil |
| 312 | Former |
| 313 | Windings |
| 314a | First tap |
| 314b | Second tap |
| 315 | Amplifier |
| 320 | A/D Converter |
| 330 | Microprocessor |
| 340 | Global Positioning and Time Unit |
| 350 | Mobile data transmission Module |

1. An apparatus for measuring a magnetic field about an electric power transmission line located along a transmission line axis comprising:
at least two first sensing coils spaced at a first distance from each other and disposed about a first axis spaced apart from the transmission line axis.

2. An apparatus for measuring a magnetic field about an electric power transmission line according to claim 1, further comprising:
a processor selectably connectable to one or more of the at least two first sensing coils for producing a signal representative of the strength of the magnetic field.

3. An apparatus for measuring a magnetic field about an electric power transmission line according to claim 1, further comprising:
at least two second sensing coils arranged at an angle to the at least two first sensing coils.

4. An apparatus for measuring a magnetic field about an electric power transmission line according to claim 2, further comprising:
at least two second sensing coils arranged at an angle to the at least two first sensing coils.

5. An apparatus for measuring a magnetic field about an electric power transmission line according to claim 1, further comprising a position and time measuring unit.

6. An apparatus for measuring a magnetic field about an electric power transmission line according to claim 2, further comprising a position and time measuring unit.

7. An apparatus for measuring a magnetic field about an electric power transmission line according to claim 3, further comprising a position and time measuring unit.

8. An apparatus for measuring a magnetic field about an electric power transmission line according to claim 1, further comprising a data transmission module.

9. An apparatus for measuring a magnetic field about an electric power transmission line according to claim 2, further comprising a data transmission module.

10. An apparatus for measuring a magnetic field about an electric power transmission line according to claim 5, further comprising a data transmission module.

11. An apparatus for measuring a magnetic field about an electric power transmission line according to claim 1, further comprising a solar power unit.

12. An apparatus for measuring a magnetic field about an electric power transmission line according to claim 2, further comprising a solar power unit.

13. An apparatus for measuring a magnetic field about an electric power transmission line according to claim 5, further comprising a solar power unit.

14. An apparatus for measuring a magnetic field about an electric power transmission line according to claim 8, further comprising a solar power unit.

15. An apparatus for measuring a magnetic field about an electric power transmission line according to claim 1, further comprising a waterproof container enclosing the at least two first sensing coils.

16. A method for the measurement of a magnetic field about an electric power transmission line comprising:
measuring a current induced in a first sensing coil;
measuring a current induced in a second sensing coil;
measuring a current induced in both the first sensing coil and the second sensing coil; and
calculating a value representative of a strength of the magnetic field.

17. A method for the measurement of a magnetic field about an electric power transmission line according to claim 16, further comprising
measuring a position of the first sensing coil and the second sensing coil.

18. A method for the measurement of a magnetic field about an electric power transmission line according to claim 16, further comprising
transmitting the values of the magnetic field at periodic intervals to a processor.

19. A method for the measurement of a magnetic field about an electric power transmission line according to claim 16, further comprising
transmitting the values of the magnetic field at periodic intervals to a processor.

20. A method for the measurement of transmitted power in an electric line comprising:
measuring a current induced in a first sensing coil;
measuring a current induced in a second sensing coil;
measuring a current induced in both the first sensing coil and the second sensing coil;
calculating a value of the magnetic field;
calculating the transmitted power using the value of the magnetic field and a nominal voltage.
